(19) United States
(12) Patent Application Publication
(10) Pub. No.: US 2024/0266221 A1
(43) Pub. Date: Aug. 8, 2024

(54) PROCESSING METHOD OF WORKPIECE

(71) Applicant: DISCO CORPORATION, Tokyo (JP)

(72) Inventors: Jinyan ZHAO, Tokyo (JP); Shigenori HARADA, Tokyo (JP)

(21) Appl. No.: 18/426,513

(22) Filed: Jan. 30, 2024

(30) Foreign Application Priority Data
Feb. 3, 2023 (JP) 2023-015573

(51) Int. Cl. H01L 21/786; H01L 21/67

(52) U.S. Cl. CPC H01L 21/786; H01L 21/67092; H01L 2221/68309

(57) ABSTRACT

A processing method of a workpiece includes a division step of dividing into a plurality of chips the workpiece held on a first surface of a sheet, a tightly bonding step of, after the division step, heating at least either the sheet or the workpiece to soften the sheet and tightly bonding the sheet to the chips, and a cleaning step of, after the tightly bonding step, cleaning the workpiece.

### BACKGROUND OF THE INVENTION

### Field of the Invention

The present invention relates to a processing method of a workpiece.

### Description of the Related Art

When performing processing such as grinding or cutting of a workpiece like a semiconductor wafer, a self-adhesive tape is bonded from a side of a back surface of a ring-shaped frame to close its opening, and with the workpiece bonded to a self-adhesive surface of a portion of the self-adhesive tape, the portion closing the opening, the processing is performed. Japanese Patent Laid-open No. 2019-153689 discloses a technology that, with a workpiece, on a front surface of which a plurality of device regions are defined and formed by scribe lines, held on a self-adhesive tape, the workpiece is divided into a plurality of chips along the scribe lines, followed by cleaning of the workpiece.

### SUMMARY OF THE INVENTION

The technology of the related art however involves a problem that, if the chips divided from the workpiece are loose from the tape at the time of cleaning of the divided workpiece, chip fly-off that the chips are caused to be peeled off and fly off from the tape by cleaning fluid or air blown to dry the chips after the cleaning occurs. For the technology of the related art, there is hence a desire to prevent chip fly-off when cleaning.

The present invention therefore has as an object thereof the provision of a processing method of a workpiece, which can prevent chip fly-off during cleaning of a plurality of chips that are divided from the workpiece and are held on a sheet.

In accordance with an aspect of the present invention, there is provided a processing method of a workpiece, including a division step of dividing the workpiece held on a first surface of a sheet into a plurality of chips, a tightly bonding step of, after the division step, heating at least either the sheet or the workpiece to soften the sheet and tightly bonding the sheet to the chips, and a cleaning step of, after the tightly bonding step, cleaning the chips.

Preferably, the tightly bonding step places the sheet at a second surface thereof on a holding table, the second surface being on a side opposite to the first surface, and holds the sheet by suction on the holding table.

Preferably, the division step includes a division starting point formation step of forming division starting points in the workpiece, and an expansion step of expanding the sheet to divide the workpiece along the division starting points.

Preferably, the processing method further includes an inter-chip spacing widening step of, after the division step and before the tightly bonding step, expanding the sheet to widen a spacing between the chips.

The present invention exhibits an advantageous effect that chip fly-off can be prevented during cleaning of a plurality of chips that are divided from a workpiece and are held on a sheet.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view depicting a configuration example of a processing machine for use in performing a processing method according to an embodiment of the present invention;

FIG. 2 is a partly cut-away perspective view schematically depicting an example of a cleaning unit in the processing machine of FIG. 1;

FIG. 3 is a flow chart illustrating the processing method according to the embodiment of the present invention, which is to be performed by the processing machine of FIG. 1;

FIG. 4 is a cross-sectional view depicting a division step of the processing method illustrated in FIG. 3;

FIG. 5 is a drawing illustrating cross-sectional views depicting situations before and after performing a tightly bonding step of the processing method illustrated in FIG. 3;

FIG. 6 is a cross-sectional view depicting a first modification of the tightly bonding step of FIG. 5;

FIG. 7 is a cross-sectional view depicting a second modification of the tightly bonding step of FIG. 5;

FIG. 8 is a cross-sectional view depicting a third modification of the tightly bonding step of FIG. 5;

FIG. 9 is a flow chart illustrating a modification of the division step of FIG. 4;

FIG. 10 is a cross-sectional view depicting a division starting point formation step illustrated in FIG. 9; and

FIG. 11 is a drawing illustrating cross-sectional views depicting scenes before and after performing an expansion step illustrated in FIG. 9.

### DETAILED DESCRIPTION OF THE PREFERRED EMBODIMENT

With reference to the attached drawings, a description will hereinafter be made in detail about an embodiment of the present invention. However, the present invention shall not be limited by details that will be described in the subsequent embodiment. The elements of configurations that will hereinafter be described include those readily conceivable to persons skilled in the art and substantially the same ones. Further, the configurations that will hereinafter be described can be combined appropriately. Furthermore, various omissions, replacements, and modifications of configurations can be made without departing from the spirit of the present invention.

In the embodiment to be described hereinafter, an XYZ orthogonal coordinate system will be set, and with reference to this XYZ orthogonal coordinate system, a description will be made about positional relations of individual elements or portions. A direction in a horizontal plane will be referred to as an X-axis direction, another direction orthogonal to the X-axis direction in the horizontal plane will be referred to as a Y-axis direction, and a further direction orthogonal to each of the X-axis direction and Y-axis direction will be referred to as a Z-axis direction. An XY plane that contains an X-axis and a Y-axis is parallel to the horizontal plane. The Z-axis direction orthogonal to the XY plane is a vertical direction.

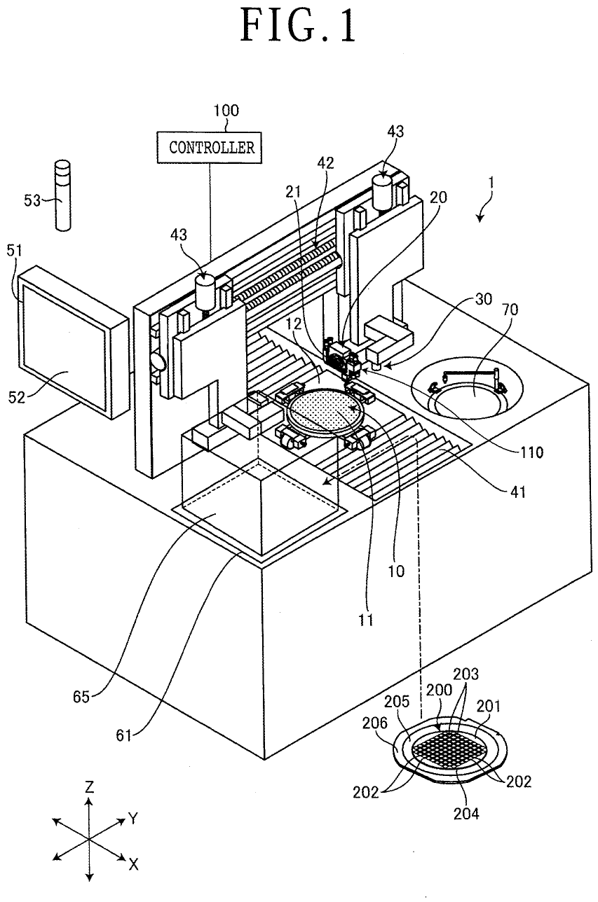

A processing machine 1 for use in performing a processing method according to the embodiment of the present invention will be described based on the drawings. FIG. 1 is a perspective view depicting a configuration example of the processing machine 1. As depicted in FIG. 1, the processing machine 1 divides a workpiece 200, on a planar front surface 201 of which a plurality of device regions are defined and formed by scribe lines 202, into a plurality of chips along the scribe lines, and then cleans the workpiece 200.

As depicted in FIG. 1, the workpiece 200 to be processed by the processing machine 1 is, for example, a disk-shaped semiconductor wafer, an optical device wafer, or the like, which uses, as a base material, silicon, sapphire, silicon carbide (SiC), gallium arsenide, glass, lithium tantalate (LT), lithium niobate (LN), or the like. The workpiece 200 includes chip-size devices 203 formed in the device regions which are defined by the scribe lines 202 and are formed in a grid pattern on the planar front surface 201. In this embodiment, a sheet 205 having self-adhesiveness is bonded to a back surface 204 of the workpiece 200 on a side opposite to the front surface 201, and an annular frame 206 is attached to an outer edge portion of the sheet 205, although the present invention is not limited to this configuration. The sheet 205 includes a base material made of resin having non-adhesiveness and flexibility, and a self-adhesive layer stacked on the base material and made of resin having self-adhesiveness and flexibility. The sheet 205 is a self-adhesive tape having a self-adhesive layer to be bonded to the workpiece 200 and the frame 206, or a sheet including only a base material, which is made of thermoplastic resin, without any adhesive layer and to be thermocompression-bonded to the workpiece 200 and the frame 206. Alternatively, the workpiece 200 may be a rectangular package substrate having a plurality of devices 203 packaged with resin, a ceramic plate, a glass plate, or the like in this embodiment.

As depicted in FIG. 1, the processing machine 1 includes a holding table 10, a processing unit 20, a camera 30, an X-axis direction moving unit 41, a pair of Y-axis direction moving units 42, a pair of Z-axis direction moving units 43, a display unit 51, an input unit 52, an alarm unit 53, a cassette stage 61, a cleaning unit 70, and a controller 100. It is to be noted that another processing unit and another camera are also arranged corresponding to one of the paired Z-axis direction moving units 43, the one Z-axis direction moving unit 43 being disposed on a front side in the Y-axis direction. However, these processing unit and camera will not be described below, as they are not seen in FIG. 1 and they are the same in configuration and function as the processing unit 20 and the camera 30.

The holding table 10 includes a disk-shaped frame body with a recessed portion formed therein, and a disk-shaped holding portion 11 fitted in the recessed portion, and is what is generally called a chuck table. The holding portion 11 of the holding table 10 includes porous ceramics or the like having numerous pores, and is connected to an undepicted vacuum suction source via an undepicted vacuum suction channel. The holding portion 11 of the holding table 10 has a top surface as a holding surface on which the workpiece 200 is placed and the placed workpiece 200 is held by suction under a negative pressure introduced from the vacuum suction source.

In this embodiment, the workpiece 200 is placed on the holding portion 11 with the front surface 201 directed upward, and the holding portion 11 holds the placed workpiece 200 by suction from the side of the back surface 204 via the sheet 205. The top surface of the holding portion 11 and a top surface of the frame body of the holding table 10 are arranged on the same horizontal plane and are formed in parallel with the XY plane as the horizontal plane. The holding table 10 is disposed on the X-axis direction moving unit 41 via a table cover and is disposed movably by the X-axis direction moving unit 41 along with the table cover in the X-axis direction parallel to the horizontal direction. The holding table 10 is also disposed rotatably by an undepicted rotary drive source about a Z-axis relative to the table cover. The Z-axis is parallel to the vertical direction and is orthogonal to the XY plane.

The processing unit 20 is configured to permit processing of the workpiece 200 based on processing conditions under control by the controller 100. The processing conditions include conditions for processing such as, for example, rotational speeds of motors, moving speeds of the processing unit 20 in the X-axis direction and Y-axis direction, an amount of cleaning fluid to be used, and a duration of use of cleaning fluid. The processing unit 20 includes, for example, a cutting blade 21. With the workpiece 200, on the front surface 201 of which the device regions are defined and formed by the scribe lines 202, being held on the sheet 205, the processing unit 20 singulates the workpiece 200 into the devices 203 by dividing the workpiece 200 into a plurality of chips with the cutting blade 21 along the scribe lines 202 under control by the controller 100. It is to be noted that the processing unit 20 may be configured to form modified layers inside the workpiece 200, grind the workpiece 200 from the back surface 204 to form cracks in the workpiece 200 while using the modified layers as starting points, and then expand the sheet 205 to singulate the workpiece 200 along the modified layers. In this embodiment, the description will be made about a case where the processing by the processing unit 20 is cutting, although the processing may be different processing such as grinding.

The camera 30 includes an imaging device that images the workpiece 200 held on the holding table 10. The imaging device is, for example, a charge-coupled device (CCD) imaging device or a complementary metal oxide semiconductor (CMOS) imaging device. The camera 30 images the front surface 201 of the workpiece 200 that is held on the holding table 10 and is to be cut by the processing unit 20, acquires an image for use in performing a positional registration between the workpiece 200 and the processing unit 20, that is, an alignment, and outputs the acquired image to the controller 100. In addition, the camera 30 images the front surface 201 of the workpiece 200 that is held on the holding table 10 and has been cut by the processing unit 20, acquires an image for use in performing a kerf check that automatically confirms whether or not the cutting of the workpiece 200 has been performed in normal ranges, and outputs the acquired image to the controller 100. In this embodiment, the camera 30 is fixed adjacent the processing unit 20 and therefore moves integrally with the processing unit 20.

The X-axis direction moving unit 41, the Y-axis direction moving unit 42, and the Z-axis direction moving unit 43 relatively move the holding table 10 and the processing unit 20 with the camera 30 in the X-axis direction, the Y-axis direction, and the Z-axis direction, respectively. In this embodiment, the X-axis direction moving unit 41 moves the holding table 10 along the X-axis direction relative to the processing unit 20 and the camera 30. In this embodiment, the Y-axis direction moving unit 42 and the Z-axis direction moving unit 43 move the processing unit 20 and the camera 30 together in the Y-axis direction and the Z-axis direction, respectively, relative to the holding table 10.

The X-axis direction moving unit 41, the Y-axis direction moving unit 42, and the Z-axis direction moving unit 43 are each a known ball screw mechanism having a motor, a ball screw, and guides. The X-axis direction moving unit 41 includes the ball screw disposed rotatably about an axis of rotation parallel to the X-axis, the motor that rotates the ball screw about the axis of rotation, and the guides that support the holding table 10 movably in the X-axis direction. The Y-axis direction moving unit 42 includes the ball screw disposed rotatably about an axis of rotation parallel to the Y-axis, the motor that rotates the ball screw about the axis of rotation, and the guides that support the processing unit 20 and the camera 30 movably in the Y-axis direction. The Z-axis direction moving unit 43 includes the ball screw disposed rotatably about an axis of rotation parallel to the Z-axis, the motor that rotates the ball screw about the axis of rotation, and the guides that support the processing unit 20 and the camera 30 movably in the Z-axis direction. With respect to the X-axis direction moving unit 41, the Y-axis direction moving unit 42, and the Z-axis direction moving unit 43, drives of their motors are all controlled by the controller 100 in terms of speeds of movements, amounts of movements, and the like.

The X-axis direction moving unit 41, the Y-axis direction moving unit 42, and the Z-axis direction moving unit 43 each include an encoder to read a rotational position of the corresponding motor. Based on the rotational positions of the motors as read by the encoders, the X-axis direction moving unit 41, the Y-axis direction moving unit 42, and the Z-axis direction moving unit 43 detect the relative positions, in the X-axis direction, the Y-axis direction, and the Z-axis direction, of the holding table 10 and the processing unit 20 with the camera 30, and output the detected relative positions to the controller 100. Here, for the relative positions in the X-axis direction, the Y-axis direction, and the Z-axis direction, a machine's orthogonal coordinate system (XYZ coordinates) with which the processing machine 1 is provided is used. In the machine's orthogonal coordinate system, a center of the top surface of the holding portion 11 of the holding table 10 is set as an origin, for example. It is to be noted that the X-axis direction moving unit 41, the Y-axis direction moving unit 42, and the Z-axis direction moving unit 43 are not limited to the configurations which detect by the encoders the relative positions of the holding table 10 and the processing unit 20 with the camera 30, and may include respective linear scales disposed in parallel with the X-axis direction, the Y-axis direction, and the Z-axis direction and respective read heads which are disposed movably in the X-axis direction, the Y-axis direction, and the Z-axis direction by the X-axis direction moving unit 41, the Y-axis direction moving unit 42, and the Z-axis direction moving unit 43, respectively, to read graduations of the linear scales.

In an undepicted cover of the processing machine 1, the display unit 51 is disposed with a side of its display screen directed outward. The display unit 51 visibly displays, to an operator, setting screens for various conditions as to a variety of processing by the processing machine 1, such as cutting by the processing unit 20 and imaging by an imaging unit 110, acquired images and data, determination results, and the like. The display unit 51 includes a liquid crystal display or the like. In the display unit 51, the input unit 52 is included for use when the operator inputs information regarding the above-described various conditions for the processing machine 1, information regarding the display of images and the like, and so on. The input unit 52 provided in the display unit 51 includes at least one of a touch screen disposed in the display unit 51, a keyboard, or the like. It is to be noted that the display unit 51 may not be fixed on the processing machine 1 and may be included in optional communication equipment, and the optional communication equipment may be connected wirelessly or through a wire to the processing machine 1.

The alarm unit 53 is disposed at an upper portion of the undepicted cover of the processing machine 1. In this embodiment, the alarm unit 53 is a light-emitting unit including light-emitting diodes or the like, and by lighting, flickering, a light color change of the light-emitting unit, or the like, appreciably notifies the operator of errors occurring during the variety of processing by the processing machine 1, the determination results, and the like. It is to be noted that, in the present invention, the alarm unit 53 is not limited to the light-emitting unit, and may be an audio unit including a speaker or the like to produce sound and may appreciably notifies the operator of an occurring error, determination results, or the like by the sound from the audio unit.

The cassette stage 61 is a stage on which a cassette 65 as a case for holding a plurality of workpieces 200 therein is placed, and moves up and down the placed cassette 65 in the Z-axis direction. The cleaning unit 70 cleans each workpiece 200 after cutting, thereby removing contaminants such as cutting debris stuck on the workpiece 200. The processing machine 1 further includes an undepicted transfer unit, which transfers each workpiece 200 between the holding table 10, the cleaning unit 70, and the cassette 65.

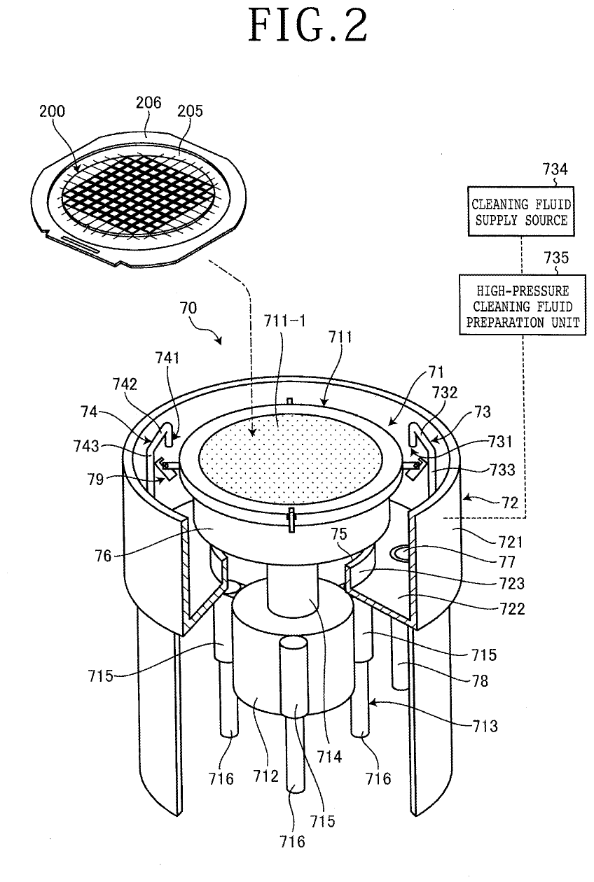

FIG. 2 is a partly cut-away perspective view schematically depicting an example of the cleaning unit 70. As depicted in FIG. 2, the cleaning unit 70 includes a spinner table mechanism 71, a cleaning fluid catch system 72 surrounding a periphery of the spinner table mechanism 71, a cleaning system 73 that cleans the workpiece 200 as an item to be cleaned, and a drying system 74 that dries the cleaned workpiece 200.

The spinner table mechanism 71 has a spinner table 711, a motor 712 that rotates the spinner table 711 about an axis along a direction perpendicular to a top surface thereof, and a support mechanism 713 that supports the motor 712 movably in an up-down direction. In an upper portion of the spinner table 711, a porous member 711-1 is disposed with a top surface thereof exposed upward. Inside the spinner table 711, a suction channel (not depicted) is arranged with one end thereof connected to an undepicted suction source and the other end thereof connected to the porous member 711-1.

When the workpiece 200 is placed on the spinner table 711, and the suction source is operated to cause a negative pressure to act on the workpiece 200 through the suction channel and the porous member 711-1, the workpiece 200 is held by suction on the spinner table 711. That is, the top surface of the spinner table 711 serves as a holding surface.

To a lower portion of the spinner table 711, an output shaft 714 is connected at an upper end thereof, and to a lower end of the output shaft 714, the motor 712 is connected. The output shaft 714 transmits to the spinner table 711 a rotational force produced by the motor 712.

The motor 712 is supported by the support mechanism 713. The support mechanism 713 includes a plurality of air cylinders 715 attached to the motor 712, and to lower portions of the respective air cylinders 715, support legs 716 are connected. When the individual air cylinders 715 are concurrently operated, the motor 712 and the spinner table 711 can be moved up or down. When loading or unloading the workpiece 200, the support mechanism 713 is operated to raise the spinner table 711 to a predetermined loading/unloading position. When cleaning the workpiece 200, the spinner table 711 is lowered to a predetermined cleaning position.

The cleaning fluid catch system 72 includes a cylindrical outer peripheral wall 721, an annular bottom wall 722 extending inward in a radial direction from a lower portion of the outer peripheral wall 721, and an inner peripheral wall 723 disposed upright upwardly from a side of an inner periphery of the bottom wall 722. The inner peripheral wall 723 internally defines a through-opening 75, through which the output shaft 714 extends. Arranged on an outer periphery of the output shaft 714 is a cover member 76 of a size sufficient to surround the inner peripheral wall 723 from a side of the outer periphery.

A drain hole 77 is disposed through the bottom wall 722, and a drain channel 78 is connected to the drain hole 77. When the cleaning fluid falls into the cleaning fluid catch system 72, the cleaning fluid is drained outside from the drain hole 77 through the drain channel 78. When the spinner table 711 is lowered to the cleaning position, the inner peripheral wall 723 is surrounded by the cover member 76, so that splashing of the cleaning fluid toward the motor 712 by way of the through-opening 75 is suppressed.

The drying system 74 has a pipe-shaped air conduit stem portion 743 extending through the bottom wall 722. The air conduit stem portion 743 is a pipe-shaped member that, on an outer side of the spinner table 711, extends upward along a direction perpendicular to the top surface of the spinner table 711 to a position higher than the top surface of the spinner table 711. To an upper end of the air conduit stem portion 743, an air conduit arm portion 742 is connected. An undepicted motor is connected to a side of a proximal end of the air conduit stem portion 743 to turn the air conduit stem portion 743, and the air conduit stem portion 743 is turned by the motor about the perpendicular direction.

The air conduit arm portion 742 is a pipe-shaped member extending in a direction perpendicular to the extending direction of the air conduit stem portion 743 over a length corresponding to a distance from the air conduit stem portion 743 to a center of the spinner table 711. To a distal end of the air conduit arm portion 742, a downwardly directed drying nozzle 741 is arranged. The drying system 74 includes an undepicted air supply source, and has a function to blow air from the drying nozzle 741 toward the workpiece 200, which is held on the spinner table 711, by way of the air conduit stem portion 743 and the air conduit arm portion 742 to remove cleaning fluid stuck on the workpiece 200.

The cleaning system 73 also has a pipe-shaped cleaning fluid conduit stem portion 733 that extends through the bottom wall 722. The cleaning fluid conduit stem portion 733 is a pipe-shaped member that, on the outer side of the spinner table 711, extends upward along the direction perpendicular to the top surface of the spinner table 711 to a position higher than the top surface of the spinner table 711. To an upper end of the cleaning fluid conduit stem portion 733, a cleaning fluid conduit arm portion 732 is connected. An undepicted motor is connected to a side of a proximal end of the cleaning fluid conduit stem portion 733 to turn the cleaning fluid conduit stem portion 733, and the cleaning fluid conduit stem portion 733 is turned by the motor about the perpendicular direction.

The cleaning fluid conduit arm portion 732 is a pipe-shaped member extending in a direction perpendicular to the extending direction of the cleaning fluid conduit stem portion 733 over a length corresponding to a distance from the cleaning fluid conduit stem portion 733 to the center of the spinner table 711. To a distal end of the cleaning fluid conduit arm portion 732, a downwardly directed cleaning nozzle 731 is arranged. The cleaning system 73 includes a cleaning fluid supply source 734 and a high-pressure cleaning fluid preparation unit 735. The high-pressure cleaning fluid preparation unit 735 of the cleaning system 73 has a function to prepare high-pressure cleaning fluid based on the cleaning fluid supplied from the cleaning fluid supply source 734. The cleaning system 73 has a function to eject the cleaning fluid from the cleaning nozzle 731 toward the workpiece 200, which is held on the spinner table 711, by way of the cleaning fluid conduit stem portion 733 and the cleaning fluid conduit arm portion 732 to remove processing debris and the like stuck on the workpiece 200. The cleaning fluid conduit stem portion 733 and the cleaning fluid conduit arm portion 732 function as a supply conduit to supply the cleaning fluid. As an alternative, two-component fluid in which air and liquid is mixed, or unpressurized liquid may be supplied instead of the high-pressure cleaning fluid.

On a side of an outer periphery of the upper portion of the spinner table 711, clamps 79 are arranged to hold the frame 206 of the workpiece 200. By a centrifugal force produced by rotation of the spinner table 711, lower weight portions of the clamps 79 are caused to move outward in a radial direction, so that upper grasping portions of the clamps 79 are caused to automatically fall inward in the radial direction, and are hence allowed to grasp the frame 206.

The controller 100 depicted in FIG. 1 includes a microcomputer and serves to control operations of individual elements of the processing machine 1 such that desired cutting processing is applied to the workpiece 200. The controller 100 therefore controls the above-mentioned individual elements of the processing machine 1 to make the processing machine 1 perform processing operations on the workpiece 200. It is to be noted that the controller 100 is a computer including a processor having a microprocessor such as a central processing unit (CPU), a storage device having a memory such as a read only memory (ROM) or a random access memory (RAM), and an input/output interface device. The processor of the controller 100 performs processing in accordance with a computer program stored in the storage device, and outputs control signals to the above-mentioned elements of the processing machine 1 to control the processing machine 1. The controller 100 executes the program to make the processing machine 1 realize the processing method of the workpiece 200.

The configuration example of the processing machine 1 has heretofore been described. It is to be noted that the configuration described above with reference to FIGS. 1 and 2 is just an example, and the configuration of the processing machine 1 is not limited to such an example. Functional configurations of the processing machine 1 can be flexibly modified according to the specifications and operations of the processing machine 1.

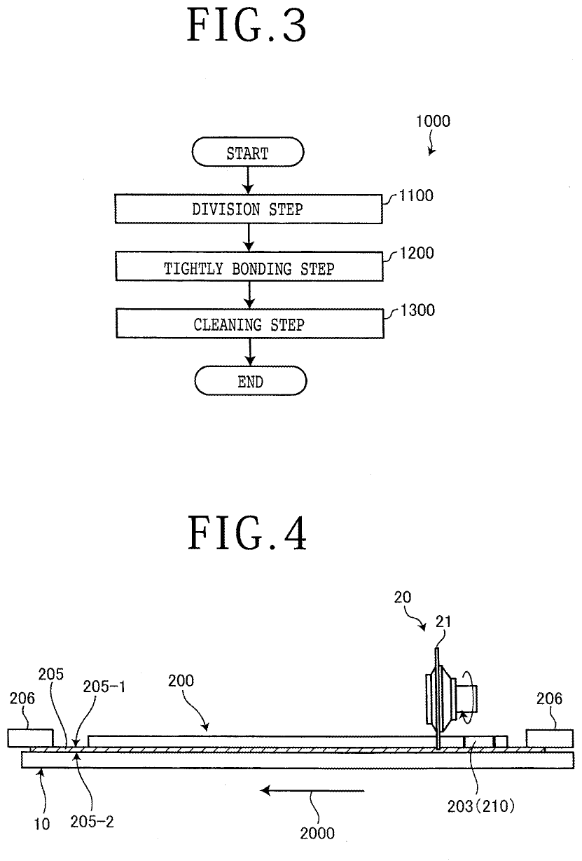

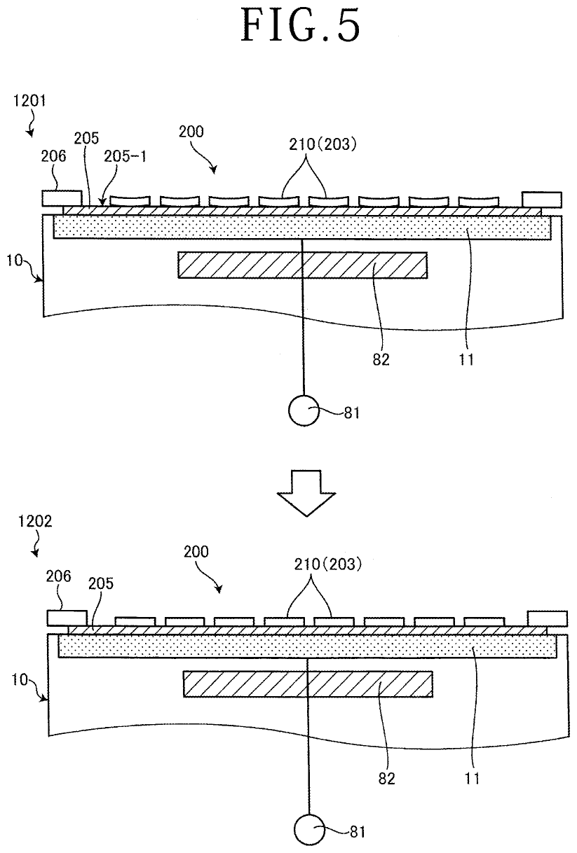

A description will next be made about a processing method 1000 according to this embodiment to be performed by the above-described processing machine 1. FIG. 3 is a flow chart illustrating the processing method 1000 according to this embodiment, which is to be performed by the above-described processing machine 1. FIG. 4 is a cross-sectional view depicting a division step 1100 of the processing method 1000 illustrated in FIG. 3. FIG. 5 is a drawing illustrating cross-sectional views depicting situations 1201 and 1202 before and after performing a tightly bonding step 1200 of the processing method 1000 illustrated in FIG. 3.

The processing method 1000 illustrated in FIG. 3 is realized through the execution of the program by the controller 100 of the processing machine 1. The processing method 1000 includes the division step 1100, the tightly bonding step 1200, and a cleaning step 1300. The processing method 1000 performs the division step 1100, the tightly bonding step 1200, and the cleaning step 1300 in this order.

The processing machine 1 first performs the division step 1100. As depicted in FIG. 4, the division step 1100 divides, into a plurality of chips 210, the workpiece 200 held on a first surface 205-1 of the sheet 205. The first surface 205-1 of the sheet 205 holds the workpiece 200 with the first surface 205-1 kept in contact with the back surface 204 of the workpiece 200. The first surface 205-1 also holds the chips 210 divided from the workpiece 200 along the scribe lines 202 (see FIG. 1). The sheet 205 has a second surface 205-2, which is a surface on a side opposite to the first surface 205-1 and is held on the holding portion 11 of the holding table 10.

In the division step 1100, with the cutting blade 21 of the processing unit 20 sequentially moved in a direction 2000, the processing machine 1 moves the cutting blade 21 to a processing height above each scribe line 202 by the Z-axis direction moving unit 43 and then cuts the workpiece 200 along the scribe line 202, so that the devices 203 on the workpiece 200 held on the first surface 205-1 of the sheet 205 are divided into the chips 210. After the workpiece 200 has been divided into the chips 210, the processing machine 1 proceeds to the next step.

Referring back to FIG. 3, the processing machine 1 performs the tightly bonding step 1200. In the tightly bonding step 1200, at least either the sheet 205 or the workpiece 200 is heated to soften the sheet 205, and the softened sheet 205 is tightly bonded to the chips 210.

As depicted in FIG. 5, the processing machine 1 has a configuration that the holding portion 11 of the holding table 10 is in communication with a suction source 81, and the workpiece 200 is held by suction on the holding table 10 under the negative pressure supplied from the suction source 81. The processing machine 1 also has a configuration that a heating unit 82 is arranged in a vicinity of a lower portion of the holding table 10, and the holding table 10 can be heated by the heating unit 82. The suction source 81 and heating unit 82 are electrically connected to the controller 100, and their operations are controlled by the controller 100.

In the tightly bonding step 1200, the processing machine 1 heats the sheet 205 via the holding table 10 by heating the holding table 10 with the heating unit 82 with the workpiece 200 held by suction on the holding table 10 under the negative pressure of the suction source 81. This heating softens the sheet 205, so that the processing machine 1 can tightly bond the softened sheet 205 to the chips 210.

In the situation 1201 of the tightly bonding step 1200, the chips 210 held on the first surface 205-1 of the sheet 205 are prone to come loose at edges thereof from the sheet 205. Especially when the processing machine 1 divides the workpiece 200 or widens the spacing between the chips 210 by expanding the sheet 205, the chips 210 are prone to come loose at the edges thereof from the sheet 205. As a reason for this problem, the chips 210 are considered to be prone to come loose at the edges thereof due to the bonding force of the sheet 205 being surpassed by warping of the chips 210 under tension of the sheet 205, or the chips 210 are considered to be prone to slide and come loose by pulling of the sheet 205.

In the situation 1201 of the tightly bonding step 1200, the processing machine 1 places the sheet 205 at the second surface 205-2 thereof, which is on the side opposite to the first surface 205-1, on the holding table 10, and then holds the sheet 205 by suction on the holding table 10. As the sheet 205 is drawn by suction when the holding portion 11 of the holding table 10 sucks the sheet 205, the chips 210 are drawn to the sheet 205. As depicted in the situation 1202, this allows the processing machine 1 to tightly bond the edges of the chips 210 to the sheet 205 softened by the heating, so that the sheet 205 can be more tightly bonded to the chips 210. After the sheet 205 has been tightly bonded to the chips 210, the processing machine 1 proceeds to the next step.

Referring back to FIG. 3, the processing machine 1 performs the cleaning step 1300. The cleaning step 1300 cleans the workpiece 200 after performing the tightly bonding step 1200. After moving the workpiece 200, which is held on the holding table 10, to the cleaning unit 70 by transfer means or the like, the processing machine 1 holds the workpiece 200 by suction on the spinner table 711. The processing machine 1 controls the cleaning system 73 in such a manner as to clean the workpiece 200, and upon completion of the cleaning of the workpiece 200, controls the drying system 74 in such a manner as to dry the cleaned workpiece 200. The processing machine 1 holds the dried workpiece 200 in the cassette 65 placed on the cassette stage 61. After the cleaning step 1300 has been completed, the processing machine 1 ends the processing method 1000 illustrated in FIG. 3.

As described above, the processing method 1000 divides, into the chips 210, the workpiece 200 held on the first surface 205-1 of the sheet 205, heats at least either the sheet 205 or the workpiece 200 to soften the sheet 205, tightly bonds the sheet 205 to the chips 210, and then cleans the chips 210. The processing method 1000 can therefore reduce chip fly-off during cleaning, by heating the sheet 205 and tightly bonding the sheet 205 in a softened state to the chips 210 before the cleaning step 1300.

If the sheet 205 does not have self-adhesiveness, it is preferred to use, for example, a polyolefin sheet such as a polyethylene sheet or a polypropylene sheet, a polystyrene sheet, or the like. Even if the sheet 205 does not have self-adhesiveness, this allows the processing method 1000 to heat the sheet 205 and to tightly bond the sheet 205 in a softened state to the chips 210, thereby enabling reduction of chip fly-off during cleaning.

In the tightly bonding step 1200, the processing method 1000 places the sheet 205 at the second surface 205-2 thereof, which is on the side opposite to the first surface 205-1, on the holding table 10, and with the sheet 205 held by suction on the holding table 10, heats at least either the sheet 205 or the workpiece 200, thereby enabling shortening of the time required to tightly bond the chips 210 to the sheet 205.

In the processing method 1000, at least either the sheet 205 or the workpiece 200 is heated preferably at a heating temperature of 50° C. to 100° C. In the processing method 1000, the devices 203 of the divided chips 210 may be adversely affected in quality if the heating temperature is higher than 100° C., and the chips 210 that are loose from the sheet 205 may not be tightly bonded if the heating temperature is lower than 50° C. It has been successfully confirmed that, if the heating temperature is 50° C. or higher in the processing method 1000, the chips 210 are tightly bonded to the sheet 205 in a heating time of two minutes without suction of the sheet 205, and the chips 210 are tightly bonded to the sheet 205 in 30 to 60 seconds with suction of the sheet 205.

In this embodiment, the processing method 1000 has been described using the case where at least either the sheet 205 or the workpiece 200 is heated using the heating unit 82 arranged in the holding table 10, although not limited to the above-described case. For example, the processing method 1000 may use a processing machine 1 of a configuration that warm air or infrared rays are supplied from the side of the first surface 205-1 of the sheet 205 to heat the sheet 205.

### First Modification of Tightly Bonding Step

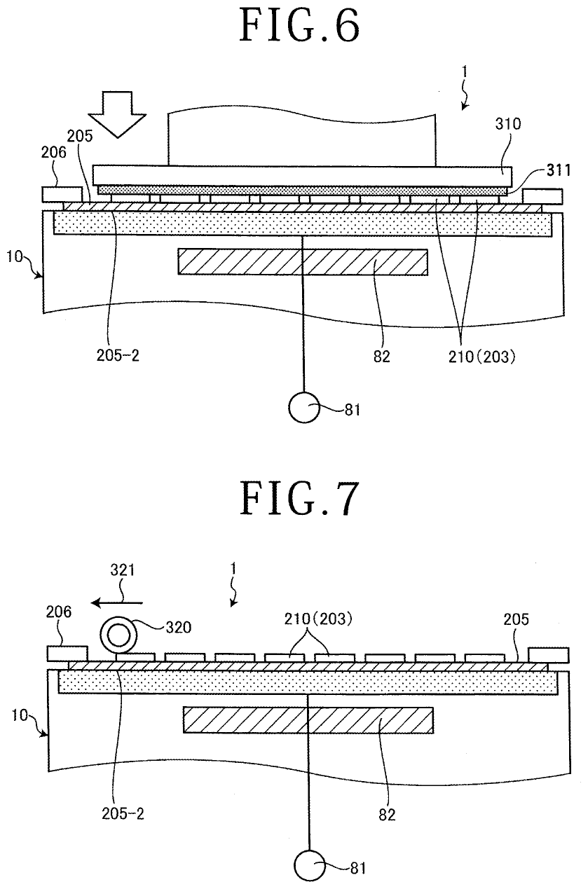

The tightly bonding step 1200 of the processing method 1000 may perform the above-mentioned heating and holding by suction concurrently with pressing or one after the other in this order. FIG. 6 is a cross-sectional view depicting a first modification of the tightly bonding step 1200.

As depicted in FIG. 6, the processing machine 1 further includes a pad 310 having an elastic member 311. The pad 310 is movable in the vertical direction, for example, by an undepicted elevating unit, and is pressed from above in the vertical direction against the chips 210 of the workpiece 200 held on the holding table 10. In the tightly bonding step 1200, the processing machine 1 can hold the sheet 205 at the second surface 205-2 thereof, which is on the side opposite to the first surface 205-1, on the holding table 10 and hold the sheet 205 by suction on the holding table 10, and at the same time, with the chips 210 pressed against the sheet 205 by the pad 310 via the elastic member 311 interposed between the pad 310 and the chips 210, can heat at least either the sheet 205 or the workpiece 200. As the processing method 1000 thus performs the heating while pressing the chips 210 against the sheet 205, the time required to tightly bond the sheet 205 to the chips 210 can be further shortened.

### Second Modification of Tightly Bonding Step

FIG. 7 is a cross-sectional view depicting a second modification of the tightly bonding step 1200. As depicted in FIG. 7, the processing machine 1 further includes a roller 320 that can press top surfaces of the chips 210 of the workpiece 200. The roller 320 is movable in the vertical direction, for example, by an undepicted elevating unit and is rotationally movable in a moving direction 321 while pressing the chips 210 of the workpiece 200 held on the holding table 10. In the tightly bonding step 1200, the processing machine 1 can hold the sheet 205 at the second surface 205-2 thereof, which is on the side opposite to the first surface 205-1, on the holding table 10, and with the sheet 205 held by suction on the holding table 10 and also with the holding table 10 heated by the heating unit 82, can move the roller 320 in the moving direction 321 while pressing the top surfaces of the chips 210 of the workpiece 200. As the processing method 1000 thus performs the heating while pressing the chips 210 against the sheet 205, the time required to tightly bond the sheet 205 to the chips 210 can be further shortened.

### Third Modification of Tightly Bonding Step

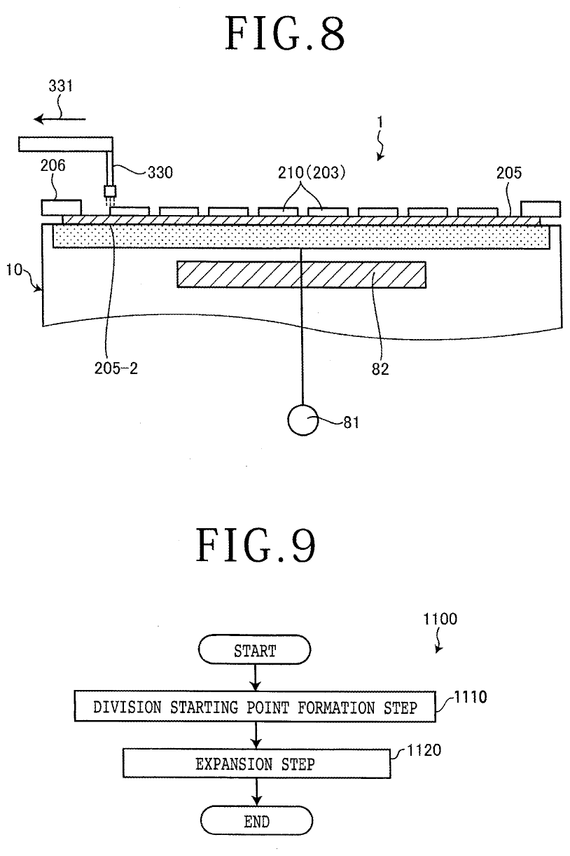

FIG. 8 is a cross-sectional view depicting a third modification of the tightly bonding step 1200. As depicted in FIG. 8, the processing machine 1 further includes a nozzle 330 that can eject fluid against surfaces of the chips 210 of the workpiece 200. The nozzle 330 is movable in the vertical direction, for example, by an undepicted elevating unit and is capable of ejecting the fluid from above toward the surfaces of the chips 210 of the workpiece 200, which is held on the holding table 10. The fluid includes, for example, gas, liquid, and the like. The nozzle 330 may be, for example, a twin-fluid nozzle that ejects gas and liquid. The nozzle 330 is configured to permit pressing of the chips 210 from above by supplying the fluid to the surfaces of the chips 210. In the tightly bonding step 1200, the processing machine 1 can hold the sheet 205 at the second surface 205-2 thereof, which is on the side opposite to the first surface 205-1, on the holding table 10, and with the sheet 205 held by suction on the holding table 10 and also with the holding table 10 heated by the heating unit 82, can move the nozzle 330 in a moving direction 331 while ejecting the fluid toward the surfaces of the chips 210 of the workpiece 200. As the processing method 1000 can thus perform the heating while pressing the chips 210 against the sheet 205 by the fluid, the time required to tightly bond the sheet 205 to the chips 210 can be further shortened.

### Modification of Division Step

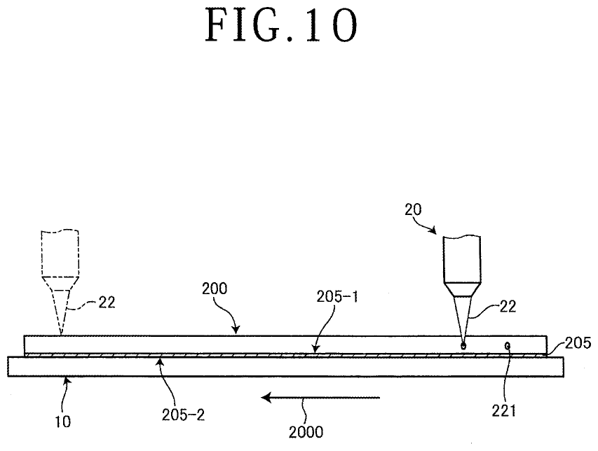

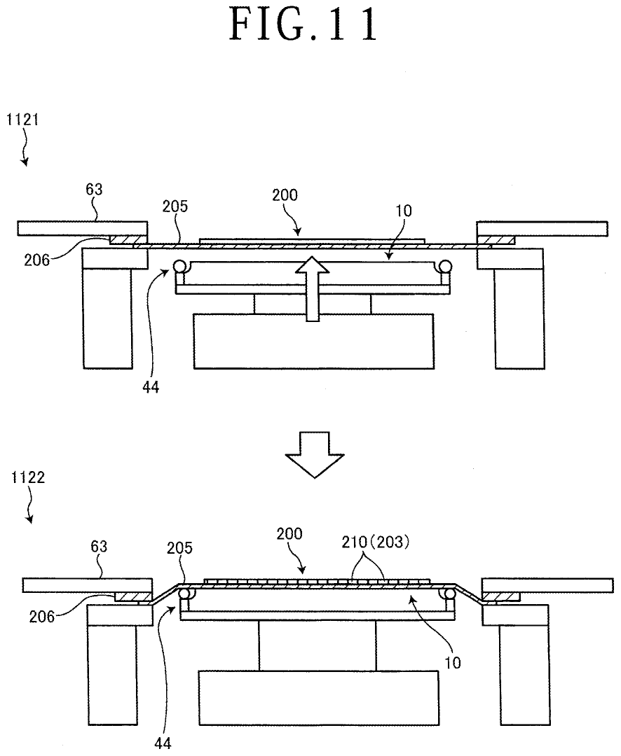

A description will next be made about a modification of the division step 1100 of the processing method 1000. FIG. 9 is a flow chart illustrating the modification of the division step 1100. FIG. 10 is a cross-sectional view depicting a division starting point formation step 1110 illustrated in FIG. 9. FIG. 11 is a drawing illustrating cross-sectional views depicting scenes 1121 and 1122 before and after performing an expansion step 1120 illustrated in FIG. 9.

As illustrated in FIG. 9, the above-mentioned division step 1100 of the processing method 1000 may have the division starting point formation step 1110 and the expansion step 1120. As the division step 1100 of the processing method 1100, the processing machine 1 first performs the division starting point formation step 1110. As depicted in FIG. 10, the division starting point formation step 1110 forms division starting points 221 in the workpiece 200. The processing unit 20 further includes an undepicted laser beam irradiation unit. Described specifically, the division starting point formation step 1110 forms the division starting points 221 along each scribe line 202 in the workpiece 200 by connection of modified layers and cracks formed by application of a laser beam 22 by the processing unit 20.

Referring back to FIG. 9, upon completion of the division starting point formation step 1110, the processing machine 1 next performs the expansion step 1120. As depicted in FIG. 11, the expansion step 1120 expands the sheet 205 in such a manner that the workpiece 200 is divided along the division starting points 221. In this modification, the processing machine 1 further includes an expansion drum 44 that can come into contact with the frame 206 held by clamp portions 63. The expansion drum 44 is provided with cylindrical roller members, which are disposed on the same plane as the top surface of the holding table 10 and are disposed rotatably about axes of rotation thereof.

As depicted in the scene 1121, after the frame 206 which surrounds the workpiece 200 with the division starting points 221 formed therein has been clamped by the clamp portions 63, the processing machine 1 brings the holding table 10 and the expansion drum 44 close to the workpiece 200, so that the holding table 10 and the expansion drum 44 are allowed to come into contact with the sheet 205. As depicted in the scene 1122, the processing machine 1 then raises the holding table 10 and the expansion drum 44, positions the workpiece 200 at an expanding position, and expands the sheet 205 in a radial direction to apply an external force to the workpiece 200. As a consequence, the processing machine 1 divides the workpiece 200 into the individual chips 210 along the division starting points 221 by the external force applied to the workpiece 200, and at the same time, widens the inter-chip spacing.

Referring back to FIG. 9, upon completion of the expansion step 1120, the processing machine 1 completes the division step 1100 and then performs the above-mentioned tightly bonding step 1200. If the sheet 205 is expanded to divide the workpiece 200 or to widen the inter-chip spacing, for example, the sheet 205 bonded to the chips 210 is stretched and moved, so that the chips 210 are prone to come loose at the edges thereof. As a reason for this problem, because the workpiece 200 has been divided into the chips 210 by stretching of the sheet 205, the chips 210 are considered to be prone to come loose at the edges thereof due to the bonding force of the sheet 205 being surpassed by warping of the chips 210 under tension of the sheet 205, or the chips 210 are considered to be prone to slide and come loose by pulling of the sheet 205. However, the above-mentioned processing method 1000, after dividing into the chips 210 the workpiece 200 held on the first surface 205-1 of the sheet 205, heats at least either the sheet 205 or the workpiece 200 to soften the sheet 205, and after tightly bonding the sheet 205 to the chips 210, cleans the chips 210. As a consequence, the processing method 1000 can reduce chip fly-off during cleaning, by tightly bonding the sheet 205 in a heated and softened state to the chips 210 before the cleaning step 1300.

The above-mentioned embodiment describes the case where the workpiece 200 is, for example, a wafer such as a disk-shaped semiconductor wafer or an optical device wafer, which uses, as a base material, silicon, sapphire, silicon carbide (SiC), gallium arsenide, glass, lithium tantalate (LT), lithium niobate (LN), or the like, although the present invention is not limited to such workpieces. For example, the workpiece 200 may also be a rectangular package substrate having a plurality of devices packaged with resin, a ceramic plate, a glass plate, or the like.

The above-mentioned sheet 205 may be in a form that a self-adhesive layer is formed as a layer stacked on a base material layer and the side of the self-adhesive layer is to be bonded to the workpiece 200, or may be made of thermoplastic resin without any adhesive layer and may be fixed to the workpiece 200 by thermocompression bonding. If not provided with any adhesive layer, the sheet 205 may preferably be a polyolefin sheet such as a polyethylene sheet or a polypropylene sheet, a polystyrene sheet, or a polyester sheet such as a polyethylene terephthalate sheet or a polyethylene naphthalate sheet.

The present invention is not limited to the details of the above-described preferred embodiment. The scope of the invention is defined by the appended claims and all changes and modifications as fall within the equivalence of the scope of the claims are therefore to be embraced by the invention.

What is claimed is:

1. A processing method of a workpiece, comprising:
a division step of dividing the workpiece held on a first surface of a sheet into a plurality of chips;
a tightly bonding step of, after the division step, heating at least either the sheet or the workpiece to soften the sheet and tightly bonding the sheet to the chips; and
a cleaning step of, after the tightly bonding step, cleaning the chips.

2. The processing method according to claim 1,
wherein the tightly bonding step places the sheet at a second surface thereof on a holding table, the second surface being on a side opposite to the first surface, and holds the sheet by suction on the holding table.

3. The processing method according to claim 1,
wherein the division step includes
a division starting point formation step of forming division starting points in the workpiece, and
an expansion step of expanding the sheet to divide the workpiece along the division starting points.

4. The processing method according to claim 1, further comprising:
an inter-chip spacing widening step of, after the division step and before the tightly bonding step, expanding the sheet to widen a spacing between the chips.
